(19) United States
(12) Patent Application Publication
(10) Pub. No.: US 2018/0342539 A1
(43) Pub. Date: Nov. 29, 2018

(54) ARRAY SUBSTRATE AND METHOD FOR MANUFACTURING THE SAME

(71) Applicant: SHENZHEN CHINA STAR OPTOELECTRONICS TECHNOLOGY CO., LTD., Shenzhen, Guangdong (CN)

(72) Inventors: Weina YONG, Shenzhen (CN); Xiangyang XU, Shenzhen (CN)

(21) Appl. No.: 15/572,494

(22) PCT Filed: Jun. 22, 2017
(86) PCT No.: PCT/CN2017/089617

§ 371 Date: Nov. 7, 2017

(30) Foreign Application Priority Data
May 25, 2017 (CN) 201710377877.6

(51) Int. Cl. H01L 27/12

(52) U.S. Cl. CPC H01L 27/1244; G02F 1/13454; H01L 27/1262

(57) ABSTRACT

An array substrate and a method for manufacturing the same are provided. The array substrate comprises a display area and a non-display area, wherein the non-display area includes a gate driver on array (GOA) region; wherein the GOA region comprises a first metal layer, an insulating layer, a second metal layer, and a protective layer sequentially formed from bottom to top; and wherein the second metal layer is connected to the first metal layer via a through-hole, and the protective layer covers the second metal layer for protecting a plurality of circuits in the GOA region from deterioration.

### FIELD OF THE DISCLOSURE

The present disclosure relates to the field of displaying techniques, and more particularly to an array substrate and a method for manufacturing the same.

### BACKGROUND

Thin film transistor liquid crystal displays (TFT-LCDs) have gradually developed to have an extremely narrow frame and have a low manufacturing cost. To achieve such objectives, more and more panel manufacturers have introduced the technique of gate driver on array (GOA) or an array substrate row driving circuit (that is, directly forming the gate driving circuits on the array substrate), into the panel.

With development of narrow frames and high resolution panels, circuit structure in a GOA region occupies more and more area at both sides of the display area, thus further reducing area size for frame glue, and even inevitably cover a portion of the circuit structure in the GOA region. For transmittance of electrical signals, a large number of through-holes are formed in the circuit structure of the GOA region. Regarding the array substrate at the lower side of the panel, each through-hole is formed with indium tin oxide (ITO) at an uppermost portion of the through-hole for connecting the signal lines on different layers, and the ITO directly contacts the frame glue after cell formation. However, all currently used frame glues, after being applied to the panel, will cause deterioration of the ITO in the circuits of the GOA region disposed below the frame glue because it is found that, after high temperature and high humidity testing, water absorption or adhesion problem ultimately results in failure of the panel, affecting manufacturing yield and performance of the panel.

Therefore, to solve the problems in the prior art, there is a need to provide an array substrate and a method for manufacturing the same.

### SUMMARY OF THE DISCLOSURE

The present disclosure provides an array substrate and a method for manufacturing the same, which prevents indium tin oxide (ITO) in the GOA region of the array substrate from deterioration, and raises the manufacturing yield and performance of the panel.

The present disclosure provides an array substrate, comprising a display area and a non-display area, wherein the non-display area comprises a Gate Driver on Array (GOA) region; wherein the GOA region comprises a first metal layer, an insulating layer, a second metal layer, and a protective layer sequentially formed from bottom to top; and wherein,

the second metal layer is connected to the first metal layer via a through-hole, and the protective layer covers the second metal layer for protecting a plurality of circuits in the GOA region from deterioration;

the first metal layer is a gate metal layer, the insulating layer is a gate insulating layer, the second metal layer is a source/drain metal layer, and the protective layer is a passivation layer;

the second metal layer extends to the through-hole and is connected to the first metal layer.

According to the array substrate of the present disclosure, the GOA region further comprises an active layer formed between the insulating layer and the second metal layer.

According to the array substrate of the present disclosure, the through-hole extends through the insulating layer.

According to the array substrate of the present disclosure, the protective layer has a thickness of 1-2 micrometers.

The present disclosure further provides an array substrate comprising a display area and a non-display area, wherein the non-display area comprises a Gate Driver on Array (GOA) region; wherein the GOA region comprises a first metal layer, an insulating layer, a second metal layer, and a protective layer sequentially formed from bottom to top; and wherein,

the second metal layer is connected to the first metal layer via a through-hole, and the protective layer covers the second metal layer for protecting a plurality of circuits in the GOA region from deterioration.

According to the array substrate of the present disclosure, the first metal layer is a gate metal layer, the insulating layer is a gate insulating layer, the second metal layer is a source/drain metal layer, and the protective layer is a passivation layer.

According to the array substrate of the present disclosure, the GOA region further comprises an active layer formed between the insulating layer and the second metal layer.

According to the array substrate of the present disclosure, the through-hole extends through the insulating layer.

According to the array substrate of the present disclosure, the second metal layer extends to the through-hole and is connected to the first metal layer.

According to the array substrate of the present disclosure, the protective layer has a thickness of 1-2 micrometers.

In accordance with the above object, the present disclosure further provides a method for manufacturing an array substrate, comprising:

sequentially forming a first metal layer and an insulating layer in a Gate Driver on Array (GOA) region of the substrate;

forming a through-hole in the insulating layer, wherein the first metal layer is disposed at bottom of the through-hole;

forming a second metal layer on the insulating layer, wherein the second metal layer is connected to the first metal layer via the through-hole; and

forming a protective layer on the second metal layer, wherein the protective layer covers the second metal layer for protecting a plurality of circuits in the GOA region from deterioration.

According to the method for manufacturing an array substrate of the present disclosure, an active layer is further formed between the insulating layer and the second metal layer.

According to the method for manufacturing an array substrate of the present disclosure, the first metal layer is a gate metal layer, the insulating layer is a gate insulating layer, the second metal layer is a source/drain metal layer, and the protective layer is a passivation layer.

According to the method for manufacturing an array substrate of the present disclosure, the second metal layer extends to the through-hole and is connected to the first metal layer.

According to the array substrate and the method for manufacturing the same of the present disclosure, the second metal layer is directly connected to the first metal layer via the through-hole, and a protective layer is formed on the second metal layer, therefore direct contact of metal with the frame glue can be avoided, so that the circuits in the GOA region of the array substrate can be prevented from deterioration, and thus the manufacturing yield and performance of the panel are increased.

To allow the above description of the present disclosure to be more clear and comprehensive, plurality preferred embodiments are provided in detail with reference to the accompanying figures.

### BRIEF DESCRIPTION OF THE DRAWINGS

In view of the accompanying drawings and detailed description of the preferred embodiments, the technical and other advantageous effects of the present disclosure will be evident, in which:

FIG. 1 is a schematic diagram showing a structure of an array substrate according to a preferred embodiment of the present disclosure;

FIG. 2 is a schematic diagram showing a layer structure of a GOA region of an array substrate according to a preferred embodiment of the present disclosure; and

FIG. 3 is a schematic diagram showing a flow of a method for manufacturing an array substrate according to a preferred embodiment of the present disclosure.

### DETAILED DESCRIPTION

To further explain the technical means adopted by the present disclosure and the advantageous effects generated thereby, a detailed description is provided below with reference to the preferred embodiments and the accompanying drawings. However, the illustrated embodiments are just a part of those of the present disclosure, instead of all of them. The scope intended to be protected by the present disclosure includes other embodiments obtained by any person having ordinary skill in the art without labor for inventiveness.

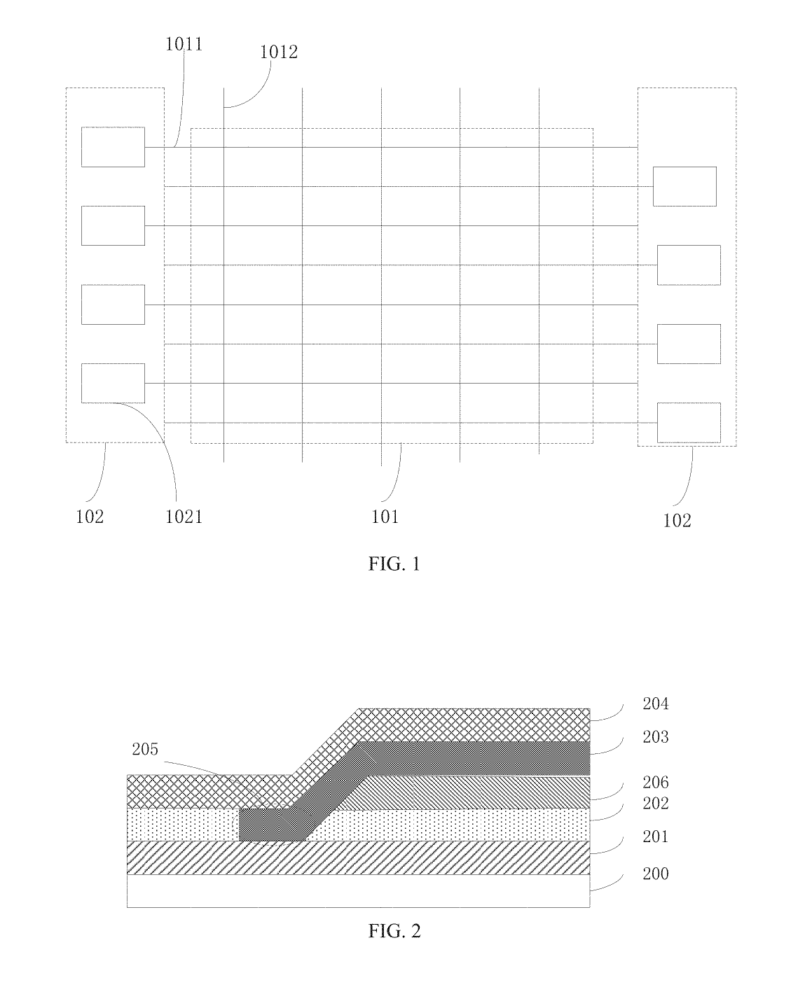

Please refer to FIG. 1. FIG. 1 is a schematic diagram showing a structure of an array substrate according to a preferred embodiment of the present disclosure. As shown in FIG. 1, the array substrate according to a preferred embodiment of the present disclosure includes a display area 101 and a non-display area (not indicated in the figure). The non-display area includes at least one gate driver on array (GOA) regions 102. A plurality of data lines 1012 and a plurality of scan lines 1011 are disposed in a cross arrangement in the display area 101. The GOA regions 102 are disposed at both sides of the display area 101. GOA circuits integrated in the GOA regions 101. The GOA circuits include a plurality of GOA units 1021 used to output the scan signals. The scan signals in turn are output to the display area 101 of the array substrate for driving the pixels in the display area 101 to be at an on state or on an off state.

During manufacture of a display panel, frame glue is generally adhered to the array substrate. However, with development of narrow frames and high resolution panels, it is inevitable that the frame glue might be adhered to the GOA regions 102. In accordance with the present disclosure, which proposes changing the layer structure of the GOA regions 102 of the array substrate, direct contact of the frame glue with the metal lines used for transmitting signals can be avoided. Therefore, the circuits in the GOA regions of the array substrate can be prevented from deterioration, raising manufacturing yield and performance of the panel.

A detailed description for a layer structure of a GOA region of the array substrate is provided below. Please refer to FIG. 2, where FIG. 2 is a schematic diagram showing a layer structure of a GOA region of an array substrate according to a preferred embodiment of the present disclosure. As shown in FIG. 2, a first metal layer 201, an insulating layer 202, a second metal layer 203, and a protective layer 204 are sequentially formed from bottom to top in the GOA region of the array substrate. The second metal layer 203 is connected to the first metal layer 201 via a through-hole 203 (i.e., the portion encircled by the dotted line). The protective layer 204 covers the second metal layer 203 for protecting a plurality of circuits in the GOA region from deterioration.

An active layer 206 is further formed between the insulating layer 202 and the second metal layer 203. The through-hole 205 extends through the insulating layer 202.

In particular, the first metal layer 201 is formed on a substrate 200. The substrate 200 can be a glass substrate, which is made of a material formed uniformly, has high transparency and low reflectivity, and has good thermal stability so that the properties thereof are stable after several times of high temperature process are performed. According to the preferred embodiment, the substrate 200 is not limited to any specific type of substrate, and when an array substrate is to be manufactured, the manufacturer can select any type of substrate 200 based on need.

The first metal layer 201 can be a metal compound conductive layer formed of multi-layered metal layers. The first metal layer 201 is generally formed by vapor evaporation, and is then patterned to form all kinds of signal lines.

The insulating layer 202 covers the first metal layer 201. The insulating layer 202 can be a layer formed of oxides, nitrides, or nitrogen oxides. Certainly, to further improve the quality of the insulating layer, the insulating layer 202 can alternatively consist of two layers.

The active layer 206 is formed on the insulating layer 202 and can be an amorphous silicon layer or a polycrystalline silicon layer.

The second metal layer 203 is formed on the active layer 206. The second metal layer 203 is generally formed by vapor evaporation, and is then patterned to form all kinds of signal lines. Please notice that in the GOA region of the array substrate, for decreasing electrical resistance, it is generally required to arrange a plurality of signal lines for transmitting the same signal on different layers, and thus it is needed to form a plurality of through-holes to connect these signal lines for transmitting the same signal.

In particular, the second metal layer 203 extends to the through-hole 205 and is connected to the first metal layer 201. Therefore, the signal lines for transmitting the same signal and formed on different layers can be connected.

The protective layer 204 is formed on the second metal layer 203. The protective layer 204, once being formed, will directly contact the frame glue. Since the protective layer 204 is not involved in transmission of the signals, the circuits in the GOA region of the array substrate can be prevented from deterioration. Preferably, the protective layer has a thickness of 1-2 micrometers.

In the preferred embodiment of the present disclosure, the first metal layer 201 is a gate metal layer, the insulating layer 202 is a gate insulating layer, the second metal layer 203 is a source/drain metal layer, and the protective layer 204 is a passivation layer.

According to the preferred embodiment of the present disclosure, the second metal layer is directly connected to the first metal layer via the through-hole, and a protective layer is formed on the second metal layer, therefore direct contact of metal with the frame glue can be avoided, so that the circuits in the GOA region of the array substrate can be prevented from deterioration, and thus manufacturing yield and performance of the panel are increased.

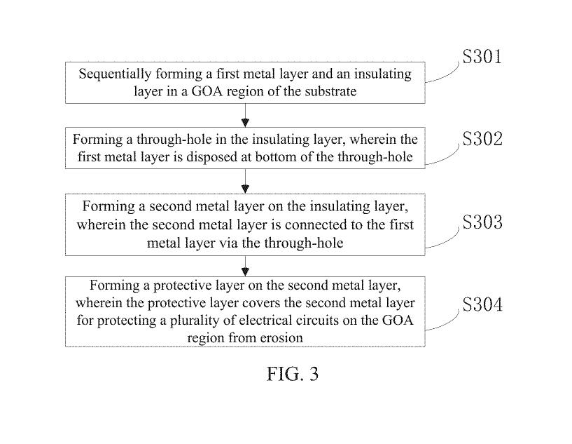

The present disclosure further provides a method for manufacturing an array substrate. Please refer to FIG. 3. FIG. 3 is a schematic diagram showing a flow of a method for manufacturing an array substrate according to a preferred embodiment of the present disclosure. As shown in FIG. 3, the method comprises:

in step S301, sequentially forming a first metal layer and an insulating layer in a gate driver on array (GOA) region of the substrate;

in step S302, forming a through-hole in the insulating layer, wherein the first metal layer is disposed at a bottom of the through-hole;

in step S303, forming a second metal layer on the insulating layer, wherein the second metal layer is connected to the first metal layer via the through-hole; and

in step S304, forming a protective layer on the second metal layer, wherein the protective layer covers the second metal layer for protecting a plurality of circuits in the GOA region from deterioration.

An active layer is further formed between the insulating layer and the second metal layer.

In particular, the first metal layer is formed on a substrate. The substrate can be a glass substrate, which is made of a uniform material, has high transparency and low reflectivity, and has good thermal stability so that the properties thereof are stable after high temperature process are performed several times. According to the preferred embodiment, the substrate is not limited to any specific type of substrate, and when an array substrate is to be manufactured, the manufacturer can select any type of substrate based on a certain need.

The first metal layer can be a metal compound conductive layer formed of multi-layered metal layers. The first metal layer is generally formed by vapor evaporation, and is then patterned to form all kinds of signal lines.

The insulating layer covers the first metal layer. The insulating layer can be of a layer formed of oxides, nitrides, or nitrogen oxides. Certainly, to further improve the quality of the insulating layer, the insulating layer can consist of two layers.

The active layer is formed on the insulating layer and can be an amorphous silicon layer or a polycrystalline silicon layer.

The second metal layer is formed on the active layer. The second metal layer is generally formed by the technique of vapor evaporation, and is then patterned to form all kinds of signal lines. Please notice that in the GOA region of the array substrate, for decreasing electrical resistance, it is generally required to arrange a plurality of signal lines for transmitting the same signal on different layers, and thus it is needed to form a plurality of through-holes to connect these signal lines for transmitting the same signal.

In particular, the second metal layer extends to the through-hole and is connected to the first metal layer. Therefore, the signal lines for transmitting the same signal and formed on different layers can be connected.

The protective layer is formed on the second metal layer. The protective layer, once being formed, will directly contact the frame glue. As the protective layer is not involved in transmission of the signals, the circuits in the GOA region of the array substrate can be prevented from deterioration. Preferably, the protective layer has a thickness of 1-2 micrometers.

In the preferred embodiment of the present disclosure, the first metal layer is a gate metal layer, the insulating layer is a gate insulating layer, the second metal layer is a source/drain metal layer, and the protective layer is a passivation layer.

According to the array substrate and the method for manufacturing the same of the present disclosure, the second metal layer is directly connected to the first metal layer via the through-hole, and a protective layer is formed on the second metal layer, therefore direct contact of metal with the frame glue can be avoided, so that the circuits in the GOA region of the array substrate can be prevented from deterioration, and thus the manufacturing yield and performance of the panel are increased.

While the present disclosure has been described with the aforementioned preferred embodiments, it is preferable that the above embodiments should not be construed as limiting of the present disclosure. Anyone having ordinary skill in the art can make a variety of modifications and variations without departing from the spirit and scope of the present disclosure as defined by the following claims.

What is claimed is:

1. An array substrate comprising a display area and a non-display area, wherein the non-display area comprises a gate driver on array (GOA) region; wherein the GOA region comprises a first metal layer, an insulating layer, a second metal layer, and a protective layer sequentially formed from bottom to top in the GOA region; and wherein,
the second metal layer is connected to the first metal layer via a through-hole, and the protective layer covers the second metal layer for protecting a plurality of circuits in the GOA region from deterioration;
the first metal layer is a gate metal layer, the insulating layer is a gate insulating layer, the second metal layer is a source/drain metal layer, and the protective layer is a passivation layer;
the second metal layer extends to the through-hole and is connected to the first metal layer.

2. The array substrate according to claim 1, wherein the GOA region further comprises an active layer formed between the insulating layer and the second metal layer.

3. The array substrate according to claim 1, wherein the through-hole extends through the insulating layer.

4. The array substrate according to claim 1, wherein the protective layer has a thickness of 1-2 micrometers.

5. An array substrate comprising a display area and a non-display area, wherein the non-display area comprises a gate driver on array (GOA) region; wherein the GOA region comprises a first metal layer, an insulating layer, a second metal layer, and a protective layer sequentially formed from bottom to top; and wherein,
the second metal layer is connected to the first metal layer via a through-hole, and the protective layer covers the second metal layer for protecting a plurality of circuits in the GOA region from deterioration.

6. The array substrate according to claim 5, wherein the first metal layer is a gate metal layer, the insulating layer is a gate insulating layer, the second metal layer is a source/drain metal layer, and the protective layer is a passivation layer.

7. The array substrate according to claim 5, wherein the GOA region further comprises an active layer formed between the insulating layer and the second metal layer.

8. The array substrate according to claim 6, wherein the GOA region further comprises an active layer formed between the insulating layer and the second metal layer.

9. The array substrate according to claim 7, wherein the through-hole extends through the insulating layer.

10. The array substrate according to claim 8, wherein the through-hole extends through the insulating layer.

11. The array substrate according to claim 5, wherein the second metal layer extends to the through-hole and is connected to the first metal layer.

12. The array substrate according to claim 6, wherein the second metal layer extends to the through-hole and is connected to the first metal layer.

13. The array substrate according to claim 5, wherein the protective layer has a thickness of 1-2 micrometers.

14. The array substrate according to claim 6, wherein the protective layer has a thickness of 1-2 micrometers.

15. A method for manufacturing an array substrate, comprising:
sequentially forming a first metal layer and an insulating layer on a gate driver on array (GOA) region of a substrate;
forming a through-hole in the insulating layer, wherein the first metal layer is disposed at a bottom of the through-hole;
forming a second metal layer on the insulating layer, wherein the second metal layer is connected to the first metal layer via the through-hole; and
forming a protective layer on the second metal layer, wherein the protective layer covers the second metal layer for protecting a plurality of circuits in the GOA region from deterioration.

16. The method for manufacturing an array substrate according to claim 15, wherein an active layer is further formed between the insulating layer and the second metal layer.

17. The method for manufacturing an array substrate according to claim 15, wherein the first metal layer is a gate metal layer, the insulating layer is a gate insulating layer, the second metal layer is a source/drain metal layer, and the protective layer is a passivation layer.

18. The method for manufacturing an array substrate according to claim 15, wherein the second metal layer extends to the through-hole and is connected to the first metal layer.

19. The method for manufacturing an array substrate according to claim 16, wherein the second metal layer extends to the through-hole and is connected to the first metal layer.

20. The method for manufacturing an array substrate according to claim 17, wherein the second metal layer extends to the through-hole and is connected to the first metal layer.
